(19) United States
(12) Patent Application Publication
(10) Pub. No.: US 2016/0261341 A1
(43) Pub. Date: Sep. 8, 2016

(54) Monolithic Integrated Laser Driver And Limiting Amplifier With Micro-Programmed Controller And Flash Memory On SOC For Fiber Optical Transceiver

(71) Applicant: SiFotonics Technologies Co., Ltd., Grand Cayman (KY)

(72) Inventors: Bo Ma, Shanghai (CN); Jack Yuan, Saratoga, CA (US); Chunmei Li, Shanghai (CN); Bo Peng, Shanghai (CN); Dong Pan, Andover, MA (US)

(21) Appl. No.: 15/052,857

(22) Filed: Feb. 24, 2016

Related U.S. Application Data
(60) Provisional application No. 62/176,786, filed on Feb. 26, 2015.

(51) Int. Cl. H04B 10/079; H01S 5/042; H04B 10/40

(52) U.S. Cl. CPC H04B 10/07955; H04B 10/40; H04B 10/0797; H01S 5/042

(57) ABSTRACT

A single-chip integrated circuit for high-speed optoelectronic transmitting and receiving is provided. The single-chip integrated circuit may include a laser driver, a limiting amplifier, a flash memory and a micro-programmed controller unit (MCU). The laser driver may be configured to accept a high-speed digital electrical signal and drive a laser diode to create an equivalent optical signal. The limiting amplifier may be configured to accept high-speed small signals from an optical detector and amplifiers and limit the high-speed small signals to create a uniform-amplitude digital electrical signal. The flash memory may be configured to store a program code and data related to transmitter and receiver circuits. The MCU may be configured to generate control signals to control the laser driver and the limiting amplifier according to the data stored in the flash memory.

### CROSS-REFERENCE TO RELATED PATENT APPLICATION(S)

The present disclosure is a non-provisional application of, and claims the priority benefit of, U.S. Provisional Patent Application No. 62/176,786, filed on 26 Feb. 2015, which is herein incorporated by reference in its entirety.

### TECHNICAL FIELD

The present disclosure is related to electronic devices. More particularly, the present disclosure is related to a monolithic integrated laser driver and limiting amplifier with micro-programmed controller and flash memory on a system-on-chip (SOC) as well as a fiber optical transceiver using the same.

### BACKGROUND

The enhanced small form-factor pluggable transceiver (SFP+) is a compact, hot-pluggable transceiver used for 10 Gbps telecommunication and data communication applications. It interfaces a network device mother board (for a switch, router, media converter or similar device) to a fiber optical cable. SFP+ is an industry standard supported by fiber devices manufacturers and network component vendors. SFP+ transceivers are designed to support SONET, Gigabit Ethernet, Fiber Channel, and other communication standards.

FIG. 1 is a schematic representation of a typical prior art SFP+ module 1. The basic components of a SFP+ module 1 include LD (Laser Driver) 2, LA (Limiting Amplifier) 3, TOSA (Transmitter Optical Sub-Assembly) 4 and ROSA (Receiver Optical Sub-Assembly) 5. TOSA and ROSA are optic components, and the others are electronic circuits. The LD and TOSA constitute transmitter circuitry, which accepts a high-speed electrical digital signal 6 and converts it to an optical digital signal. The ROSA and LA constitute receiver circuitry, which accepts a high-speed optical digital signal and converts it to an electrical digital signal 7.

There are a number of other tasks that need to be handled to improve the module's functionality. The SFP+ module 1 needs to have low-speed electrical contacts (Tx_Disalbe 13, TX_fault 14, RX_LOS 15, RS0 16, RS1 17) for control or status indicators which are defined by SFF-8431 (published by the SFF Committee). The SFP+ module 1 also needs to have an enhanced memory map with a DDMI (Digital Diagnostic Monitoring Interface) which is defined by SFF-8472 (published by the SFF Committee). The DDMI allows mother board 10 to have real-time access to device operating parameters such as temperature, supply voltage, TX bias current, TX output optical power and RX received optical power through a two-wire serial interface (typically clock SCL 11 and data SDA 12).

In most SFP+ transceiver solutions, the low-speed contacts and DDMI are implemented using discrete circuitry, for example a general purpose EEPROM (Electrical Erasable and Programmable Read Only Memory) 8 for identification purposes, by inclusion of some functions with the use of MCU (Micro-programmed Controller Unit) 9. Some solutions adopt one chip called controller IC 18 to implement all other control and DDMI functions beside the high-speed communication. So far there have not been any SFP+ module that can provide a uniform device that integrates all electrical components into one chip with the high-speed transceiver circuitry.

### SUMMARY

The following summary is illustrative only and is not intended to be limiting in any way. That is, the following summary is provided to introduce concepts, highlights, benefits and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

The present disclosure aims to provide a monolithic integrated circuit that integrates high-speed transceiver circuits (e.g., laser driver and limiting amplifier) and all other necessary circuits, such as MCU, flash memory, ADC (Analog-to-Digital Converter), temperature sensor, voltage sensor, SRAM (Static Random Access Memory), 10 (input/output) controller and two-wire serial interface, into one chip herein referred to as SOC (system on chip) to implement complete functionality of a SFP+ module.

In one aspect, a single-chip integrated circuit implementable in a transceiver module for high-speed optoelectronic transmitting and receiving may include a laser driver, a limiting amplifier, a flash memory and a micro-programmed controller unit (MCU). The laser driver may be configured to accept a high-speed digital electrical signal and drive a laser diode to create an equivalent optical signal. The limiting amplifier may be configured to accept high-speed small signals from an optical detector and amplifiers and limit the high-speed small signals to create a uniform-amplitude digital electrical signal. The flash memory may be configured to store a program code and data related to transmitter and receiver circuits. The MCU may be configured to generate control signals to control the laser driver and the limiting amplifier according to the data stored in the flash memory.

In some implementations, the single-chip integrated circuit may also include an analog-to-digital converter (ADC) configured to receive a plurality of analog signals and convert the received analog signals to digital values.

In some implementations, the single-chip integrated circuit may also include a temperature sensor configured to generate an analog temperature signal which is proportional to a temperature of the transceiver module. The ADC may convert the analog temperature signal into a digital temperature value to compensate a laser bias and a modulation current.

In some implementations, the single-chip integrated circuit may also include a voltage sensor configured to generate an analog voltage signal. The ADC may convert the analog voltage signal into a digital voltage value.

In some implementations, the single-chip integrated circuit may also include an input/output (IO) controller configured to handle low-speed electrical contacts of an optical transceiver module.

In some implementations, the single-chip integrated circuit may also include a static random access memory (SRAM) configured to perform program running and store information related to transmitter and receiver circuits.

In some implementations, the single-chip integrated circuit may also include a two-wire serial interface configured to communicate between a mother board and the transceiver module.

In one aspect, a single-chip integrated circuit for digital diagnostic monitoring in an optical transceiver module may include a laser driver, a limiting amplifier, a flash memory, and a micro-programmed controller unit (MCU). The laser driver may be configured to receive a high-speed digital electrical signal and drive a laser diode to create an equivalent optical signal. The limiting amplifier may be configured to receive high-speed small signals from an optical detector and amplifiers to limit the received signals to create a uniform-amplitude digital electrical signal. The flash memory may be configured to store program code and calibration constants for calibrating diagnostic monitoring data. The MCU may be configured to calculate and calibrate the diagnostic monitoring data which comprises temperature, supply voltage, TX bias current, TX output optical power, RX received optical power, or a combination thereof.

In some implementations, the single-chip integrated circuit may also include an analog-to-digital converter (ADC) configured to receive a plurality of analog signals from a receiver optical sub-assembly (ROSA), a transmitter optical sub-assembly (TOSA), a laser driver bias current, a temperature sensor and a voltage sensor, and convert the received analog signals to digital values.

In some implementations, the single-chip integrated circuit may also include a temperature sensor configured to generate an analog temperature signal which is proportional to a temperature of the transceiver module. The ADC may convert the analog temperature signal into a digital temperature value for temperature monitoring.

In some implementations, the single-chip integrated circuit may also include a voltage sensor configured to generate an analog voltage signal. The ADC may convert the analog temperature signal into a digital voltage value for monitoring of a power supply voltage.

In some implementations, the single-chip integrated circuit may also include a static random access memory (SRAM) for program running and storing digital diagnostic monitoring values.

In some implementations, the single-chip integrated circuit may also include a two-wire serial interface configured to report the digital diagnostic monitoring values to a mother board.

In one aspect, a single-chip integrated circuit for handling low-speed electrical contacts in an optical transceiver module may include a laser driver, a limiting amplifier, and a micro-programmed controller unit (MCU). The laser driver may be configured to receive a high-speed digital electrical signal and drive a laser diode to create an equivalent optical signal. The limiting amplifier may be configured to receive high-speed small signals from an optical detector and amplifiers to limit the received signals to create a uniform-amplitude digital electrical signal. The MCU may be configured to convey to a mother board interface a loss of signal (LOS) received from the limiting amplifier and a transmitter fault signal from the laser driver, and further configured to convey to a transmitter circuit a transmitter disable signal received from the mother board interface.

In some implementations, the single-chip integrated circuit may also include an input/output (IO) controller configured to handle low-speed electrical contacts of an optical transceiver module.

In some implementations, the single-chip integrated circuit may also include a static random access memory (SRAM) configured to perform program running and store temporary variable values.

In one aspect, a single-chip integrated circuit for firmware update may include a flash memory and a micro-programmed controller unit (MCU). The flash memory may be configured to store program code and data related to transmitter and receiver circuits. The MCU may be configured to control the flash memory and communicate between an input/output (IO) controller and the flash memory.

In some implementations, the single-chip integrated circuit may also include the input/output (IO) controller configured to download a firmware from a mother board and provide the firmware to flash memory.

In one aspect, a method of fabricating integrated high-speed optoelectronic transceiver circuits and controller circuits in a transceiver module may include: integrating a laser driver that is configured to receive a high-speed digital electrical signal and drive a laser diode to create an equivalent optical signal; integrating a limiting amplifier that is configured to receive high-speed small signals from an optical detector and amplifiers to limit the received signals to create a uniform-amplitude digital electrical signal; integrating a flash memory that is configured to store program code and data related to transmitter and receiver circuits; and integrating a micro-programmed controller unit (MCU) that is configured to generate control signals to control the laser driver and the limiting amplifier with the data stored in the flash memory.

In some implementations, the method may also include integrating an analog-to-digital converter (ADC) that is configured to receive a plurality of analog signals and convert the received analog signals to digital values.

In some implementations, the method may also include integrating a temperature sensor that is configured to generate an analog temperature signal which is proportional to a temperature of the transceiver module. The ADC may be configured to convert the analog temperature signal into a digital temperature value to compensate a laser bias and a modulation current.

In some implementations, the method may also include integrating a voltage sensor that is configured to generate an analog voltage signal. The ADC may be configured to convert the analog voltage signal into a digital voltage value.

In some implementations, the method may also include integrating an input/output (IO) controller that is configured to handle low-speed electrical contacts of the transceiver module.

In some implementations, the method may also include integrating a static random access memory (SRAM) that is configured to perform program running and store information related to the transmitter and receiver circuits.

In some implementations, the method may also include integrating a two-wire serial interface that is configured to communicate between a mother board and the transceiver module.

In one aspect, a method of digital diagnostic monitoring in an optical transceiver module may include: receiving a plurality of analog signals from a receiver optical sub-assembly (ROSA), a transmitter optical sub-assembly (TOSA), a laser driver bias current, a temperature sensor, and a voltage sensor to convert the received analog signals to digital values; calculating and calibrating diagnostic monitoring data comprising temperature, supply voltage, TX bias current, TX output optical power and RX received optical power; and storing a program code and calibration constants used for calibrating diagnostic monitoring data.

In some implementations, the method may also include generating an analog temperature signal which is proportional to a temperature of the transceiver module and converting the analog temperature signal into a digital temperature value by an analog-to-digital converter (ADC) for temperature monitoring.

In some implementations, the method may also include generating an analog voltage signal and converting the analog voltage signal into a digital voltage value by an analog-to-digital converter (ADC) for monitoring of a power supply voltage.

In some implementations, the method may also include reporting values of the digital diagnostic monitoring to a mother board.

In one aspect, a method of handling low-speed electrical contacts in an optical transceiver module may include: conveying a loss of signal (LOS) received from a limiting amplifier to a mother board interface; conveying a transmitter fault signal from a laser driver to the mother board interface; and conveying a transmitter disable signal received from the mother board interface to a transmitter circuit.

In some implementations, the method may also include conveying a receiver rate select signal received from the mother board interface to a limiting amplifier.

In some implementations, the method may also include conveying a transmitter rate select signal received from the mother board interface to the laser driver.

In one aspect, a method of firmware update may include: storing a program code and data related to transmitter and receiver circuits; and controlling a flash memory and communication between an input/output (IO) controller and the flash memory.

In some implementations, the method may also include downloading a firmware with contacts of a transceiver module.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure. The drawings may not necessarily be in scale so as to better present certain features of the illustrated subject matter.

FIG. 1 is a block diagram of a prior art SFP+ module composed of transceiver circuit, MCU and EEPROM.

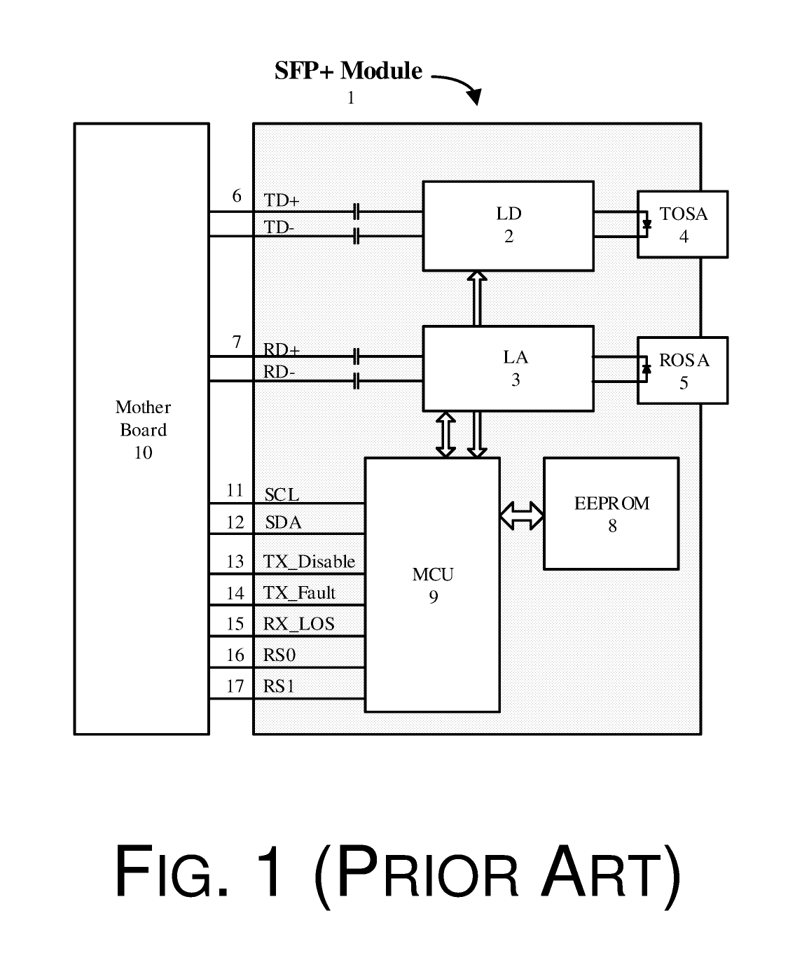

FIG. 2 is a block diagram of a prior art SFP+ module composed of transceiver circuit and one chip controller.

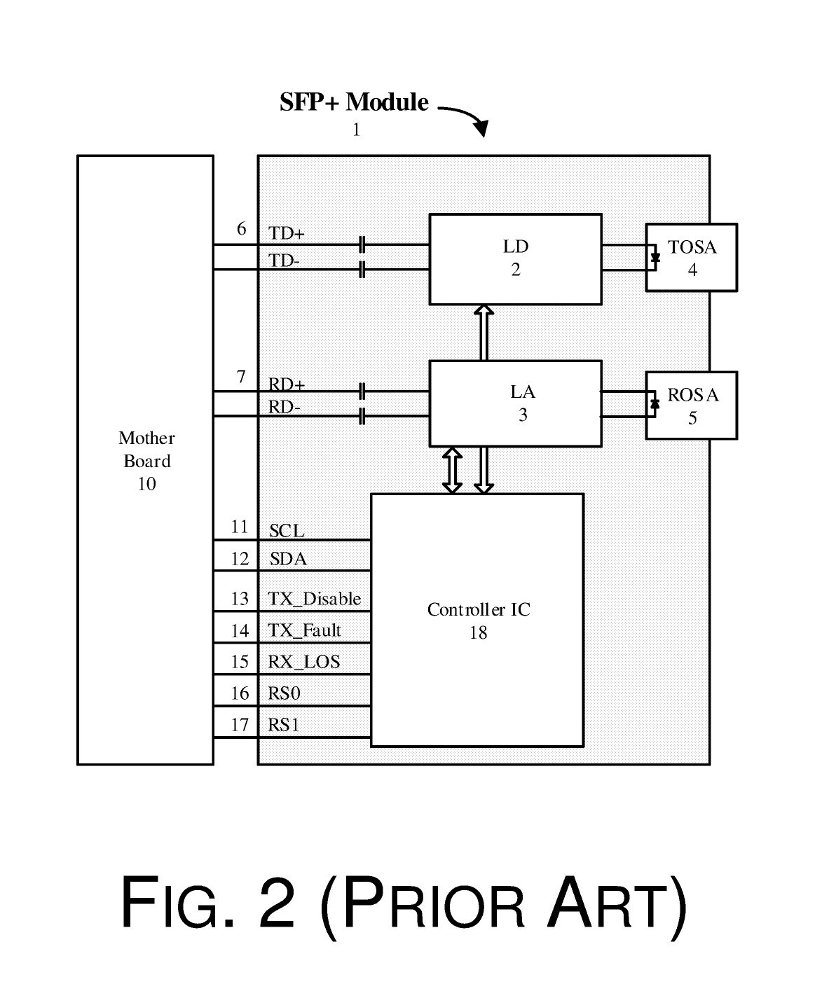

FIG. 3 is a block diagram of SFP+ module solution based on the present disclosure SOC.

FIG. 4 is a block diagram of the SOC of the SFP+ module of FIG. 3.

FIG. 5 is a flowchart of an example process in accordance with an implementation of the present disclosure.

FIG. 6 is a flowchart of an example process in accordance with another implementation of the present disclosure.

FIG. 7 is a flowchart of an example process in accordance with yet another implementation of the present disclosure.

FIG. 8 is a flowchart of an example process in accordance with still another implementation of the present disclosure.

### DETAILED DESCRIPTION OF THE PREFERRED EMBODIMENTS

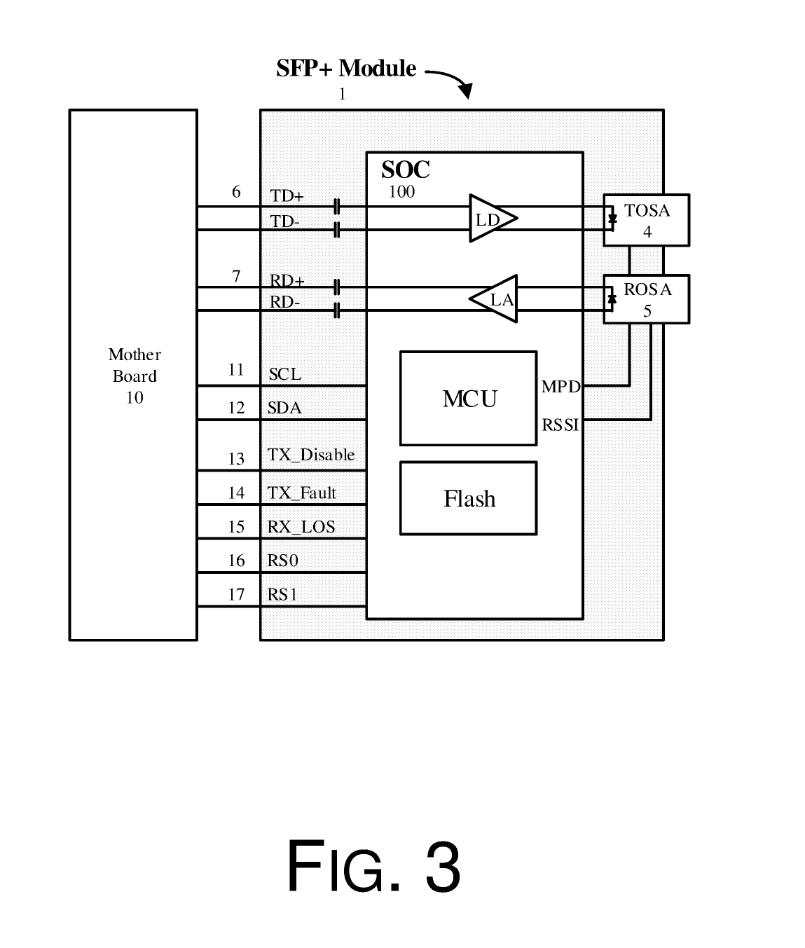

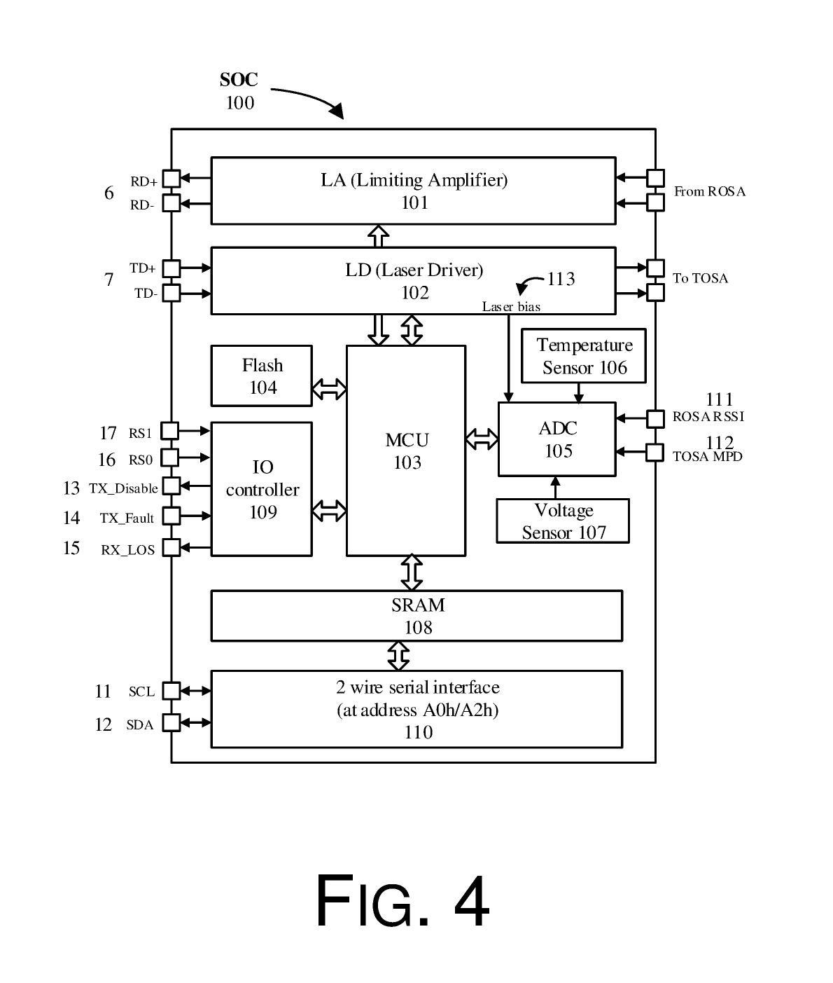

A SFP+ module based on the present disclosure is shown in FIG. 3 and FIG. 4. In the example implementation shown in FIG. 3 and FIG. 4, a high-speed transceiver (which includes laser driver (LD) 102 and limiting amplifier (LA) 101), micro-programmed controller unit (MCU) 103, flash memory 104, analog-to-digital converter (ADC) 105, temperature sensor 106, voltage sensor 107, static random-access memory (SRAM) 108, input/output (IO) controller 109 and two wire serial interface 110 at address A0h/A2h into a single chip, herein referred to as system-on-chip (SOC) 100. Advantageously, this changes three-chip/two-chips solutions in the prior art to a one-chip solution in SFP+ module application. The transceiver circuits in the SOC 100 communicate via high-speed electrical signals to the outside world. The other blocks in the SOC 100 handle all low-speed communications with a mother board. That means the electrical pins of the SFP+ module are connected to one chip.

FIG. 4 shows a detail structure of the SOC 100 in accordance with the present disclosure. MCU 103 is the core unit of the SOC 100 and controls all other blocks. LD 102 and LA 101 are directly connected to MCU 103 for multiple functions. MCU 103 can control key parameters of the LD 102 and LA 101. For example, MCU 103 can control laser bias current and modulation current or control LA output amplitude of LA 101. LD 102 and LA 101 also report status such as transmitter fault (TX_fault) 14 signal and receiver loss of signal (RX_LOS) 15 to MCU 103. Once the status of the signal(s) TX_fault and/or RX_LOS is changed, MCU 103 conveys the signal(s) to the mother board interface through 10 controller 109. MCU 103 also conveys some input contact of mother board to transceiver circuits, such as transmitter disable signal (TX_Disable) 13, receiver rate select (RS0) 16, transmitter rate select (RS1) 17.

Flash memory 104 is used in the present disclosure for several functions. Firstly, the program code (e.g., firmware) is stored in flash memory 104. New functions and features can be added to the transceiver module by firmware update. The firmware can be downloaded through the contacts such as RX_LOS/TX_Disable/RS0/RS1 of the transceiver module. Secondly, all the data of transceiver can be stored in flash memory 104. The data may include two types of values, e.g., one type of values may be used for adjusting transmitter and receiver circuits while another type of values (called calibration constant) may be used for calibrating the diagnostic monitoring data. Thirdly, SFF-8472 defines a 256-byte memory map addressed A0h for serial identification. Many transceivers generally use EEPROM to implement the identification. In contrast, embodiments in accordance with the present disclosure may use flash memory 104, MCU 103 and two-wire serial interface 110 to replace EEPROM 8.

To implement Digital Diagnostic Monitoring Interface (DDMI) defined by SFF-8472, ADC 105, temperature sensor 106, voltage sensor 107 are integrated into the SOC 100. SFF-8472 defines five types of diagnostic monitoring data, namely: temperature, power supply voltage, received optical power, transmitted optical power, and laser bias current. All of these values may be converted to real-world units such as millivolts or microwatts.

Temperature sensor 106 and ADC 105 may be utilized to implement temperature monitoring because temperature sensor 106 can generate an analog signal which is proportional to the temperature of transceiver. The temperature sensor 106 may be coupled to ADC 105 and the analog signal may be converted to digital temperature value by ADC 105. Then the converted value may be sent to MCU 103 and calibrated to units of 1/256C by MCU 103. Temperature sensor 106 may be also utilized to compensate laser bias and modulation current. When the optical power of the laser drops at high temperature, MCU 103 may increase the laser bias and modulation current according the digital temperature value which is measured by temperature sensor 106 and ADC 105.

Voltage sensor 107 and ADC 105 may be utilized to implement supply voltage monitoring. The voltage sensor 107 may be coupled to ADC 105 and the analog signal from voltage sensor 107 may be converted to digital voltage value by ADC 105. Then the converted value may be sent to MCU 103 and may be calibrated to units of 100 uV by MCU 103.

FIG. 3 shows connections from ROSA 5 and TOSA 4 to the SOC 100. The ROSA's pin RSSI (Receiver Signal Strength Indicator) 111 generates an analog signal which is proportional to the receiver optical power. The TOSA's pin MPD (monitor photo detector) 112 generates an analog signal which is proportional to the output optical power. These analog signals may be converted to digital values by ADC 105. The converted values may be sent to MCU 103 and calibrated to units of 0.1 uW by MCU 103. FIG. 3 also shows that the laser current 113 is sent to ADC 105 and the analog signal may be converted to digital current value by ADC 105. The digital current value may be calibrated to units of 2 uA by MCU 103.

All of these digital values (temperature, power voltage, transmitter optical power, receiver optical power and laser bias) may be accessed by mother board through two-wire serial interface 110.

Issues associated with prior art three-chip/two-chip SFP+ module solutions are high cost and low reliability. In order to put several chips on a small board, the design complexity is increased and PCB size has to be big enough to accommodate those chips. This can easily lead to low reliability.

Different from prior art, the present disclosure replaces prior art three-chip/two chip solution with a one-chip solution in SFP+ module. Fewer components are used to implement the SFP+ module based on the present disclosure. Only one chip, one TOSA, one ROSA and very few external capacitors, resistors are used. In some cases the TOSA and ROSA can also be replaced with COB (chip on board). This solution cut the module manufacture cost, and thus it is good for the promotion of optical telecommunication application.

Most important advantage is that the SFP+ module based on the present disclosure is more compact than the prior solutions. Especially for AOC (Active Optical Cable), a smaller package form factor can be used.

Another advantage of the present disclosure is that the power consumption drops a lot compared to discrete 3 chips solution. It is suited to data center which consumes huge power.

The present disclosure increases the internationality of SFP+ chips and improves the reliability so that SFP+ module or compatible module form-factors can be even smaller, thus reduce the cost, and suitable for more cost sensitive applications.

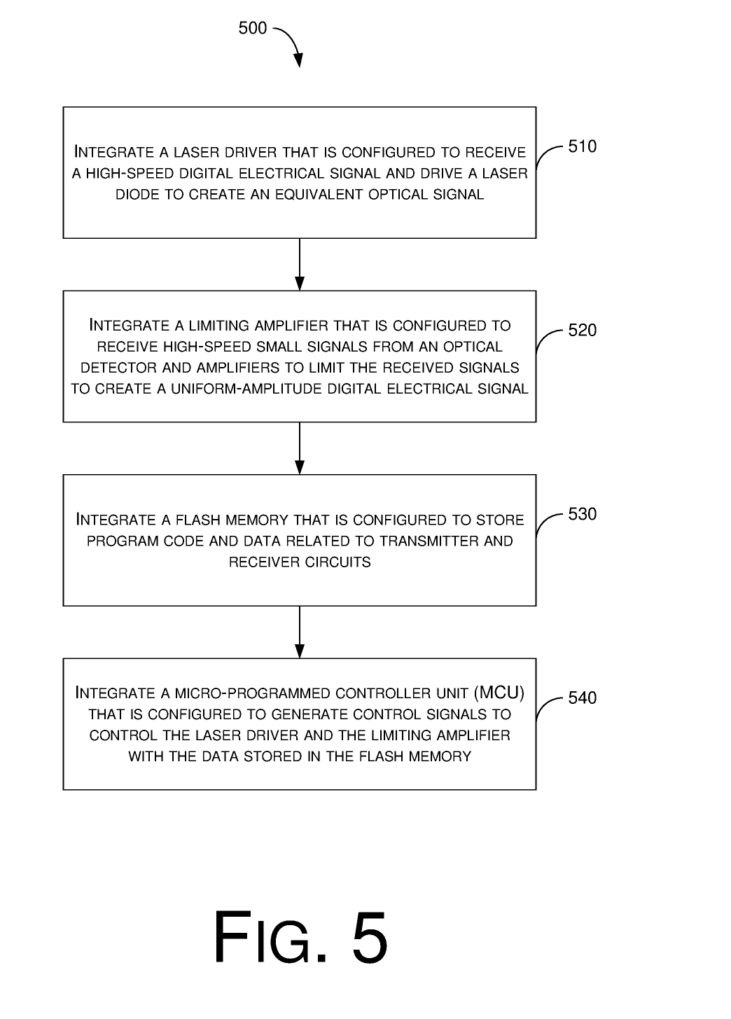

FIG. 5 illustrates an example process 500 of fabricating integrated high-speed optoelectronic transceiver circuits and controller circuits in a transceiver module in accordance with an implementation of the present disclosure. Process 500 may include one or more operations, actions, or functions as represented by one or more of blocks 510, 520, 530 and 540. Although illustrated as discrete blocks, various blocks of process 500 may be divided into additional blocks, combined into fewer blocks, or eliminated, depending on the desired implementation. The blocks of process 500 may be performed in the order shown in FIG. 5 or in any other order, depending on the desired implementation. Process 500 may be implemented for the fabrication of the SFP+ module of FIG. 3 and FIG. 4. Process 500 may begin at 510.

At 510, process 500 may involve integrating a laser driver that is configured to receive a high-speed digital electrical signal and drive a laser diode to create an equivalent optical signal. Process 500 may proceed from 510 to 520.

At 520, process 500 may involve integrating a limiting amplifier that is configured to receive high-speed small signals from an optical detector and amplifiers to limit the received signals to create a uniform-amplitude digital electrical signal. Process 500 may proceed from 520 to 530.

At 530, process 500 may involve integrating a flash memory that is configured to store program code and data related to transmitter and receiver circuits. Process 500 may proceed from 530 to 540.

At 540, process 500 may involve integrating a micro-programmed controller unit (MCU) that is configured to generate control signals to control the laser driver and the limiting amplifier with the data stored in the flash memory.

In some implementations, process 500 may additionally involve integrating an ADC that is configured to receive a plurality of analog signals and convert the received analog signals to digital values.

Additionally or alternatively, process 500 may further involve integrating a temperature sensor that is configured to generate an analog temperature signal which is proportional to a temperature of the transceiver module, wherein the ADC is configured to convert the analog temperature signal into a digital temperature value to compensate a laser bias and a modulation current.

Additionally or alternatively, process 500 may further involve integrating a voltage sensor that is configured to generate an analog voltage signal, wherein the ADC is configured to convert the analog voltage signal into a digital voltage value.

Additionally or alternatively, process 500 may further involve integrating an input/output (IO) controller that is configured to handle low-speed electrical contacts of the transceiver module.

Additionally or alternatively, process 500 may further involve integrating a static random access memory (SRAM) that is configured to perform program running and store information related to the transmitter and receiver circuits.

Additionally or alternatively, process 500 may further involve integrating a two-wire serial interface that is configured to communicate between a mother board and the transceiver module.

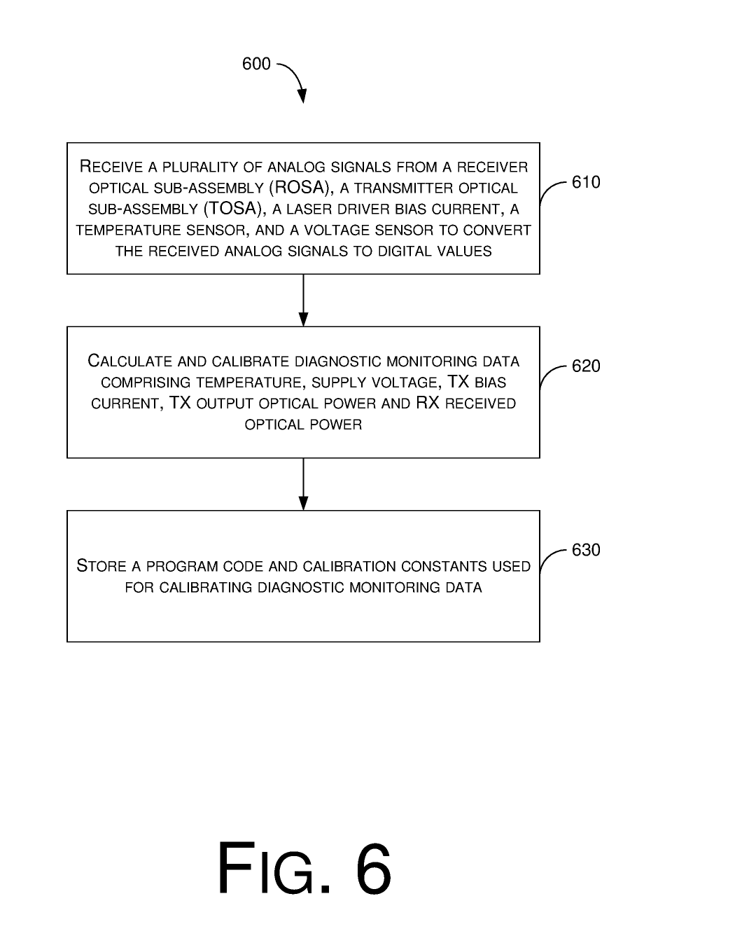

FIG. 6 illustrates an example process 600 of digital diagnostic monitoring in an optical transceiver module in accordance with an implementation of the present disclosure. Process 600 may include one or more operations, actions, or functions as represented by one or more of blocks 610, 620 and 630. Although illustrated as discrete blocks, various blocks of process 600 may be divided into additional blocks, combined into fewer blocks, or eliminated, depending on the desired implementation. The blocks of process 600 may be performed in the order shown in FIG. 6 or in any other order, depending on the desired implementation. Process 600 may be implemented by the SFP+ module of FIG. 3 and FIG. 4. Process 600 may begin at 610.

At 610, process 600 may involve receiving a plurality of analog signals from a receiver optical sub-assembly (ROSA), a transmitter optical sub-assembly (TOSA), a laser driver bias current, a temperature sensor, and a voltage sensor to convert the received analog signals to digital values. Process 600 may proceed from 610 to 620.

At 620, process 600 may involve calculating and calibrating diagnostic monitoring data comprising temperature, supply voltage, TX bias current, TX output optical power and RX received optical power. Process 600 may proceed from 620 to 630.

At 630, process 600 may involve storing a program code and calibration constants used for calibrating diagnostic monitoring data.

In some implementations, process 600 may also involve generating an analog temperature signal, which is proportional to a temperature of the transceiver module, and converting the analog temperature signal into a digital temperature value by an ADC for temperature monitoring.

Alternatively or additionally, process 600 may also involve generating an analog voltage signal and converting the analog voltage signal into a digital voltage value by an ADC for monitoring of a power supply voltage.

Alternatively or additionally, process 600 may further involve reporting values of the digital diagnostic monitoring to a mother board.

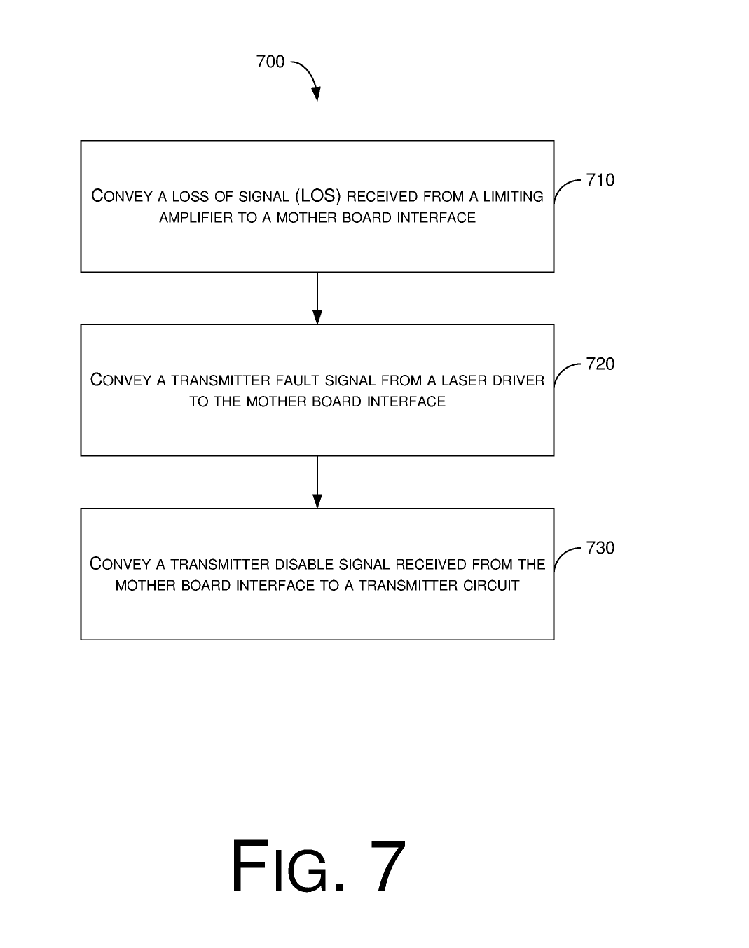

FIG. 7 illustrates an example process 700 of handling low-speed electrical contacts in an optical transceiver module in accordance with an implementation of the present disclosure. Process 700 may include one or more operations, actions, or functions as represented by one or more of blocks 710, 720 and 730. Although illustrated as discrete blocks, various blocks of process 700 may be divided into additional blocks, combined into fewer blocks, or eliminated, depending on the desired implementation. The blocks of process 700 may be performed in the order shown in FIG. 7 or in any other order, depending on the desired implementation. Process 700 may be implemented by the SFP+ module of FIG. 3 and FIG. 4. Process 700 may begin at 710.

At 710, process 700 may involve conveying a loss of signal (LOS) received from a limiting amplifier to a mother board interface. Process 700 may proceed from 710 to 720.

At 720, process 700 may involve conveying a transmitter fault signal from a laser driver to the mother board interface. Process 700 may proceed from 720 to 730.

At 730, process 700 may involve conveying a transmitter disable signal received from the mother board interface to a transmitter circuit.

In some implementations, process 700 may also involve conveying a receiver rate select signal received from the mother board interface to a limiting amplifier.

Alternatively or additionally, process 700 may further involve conveying a transmitter rate select signal received from the mother board interface to the laser driver.

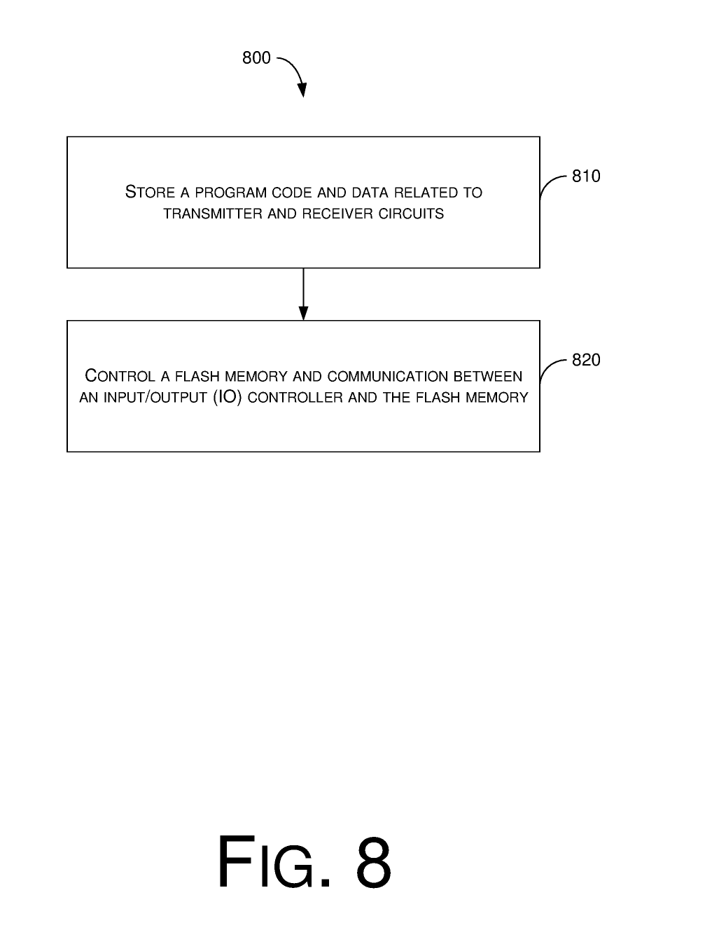

FIG. 8 illustrates an example process 800 of firmware update in accordance with an implementation of the present disclosure. Process 800 may include one or more operations, actions, or functions as represented by one or more of blocks 810 and 820. Although illustrated as discrete blocks, various blocks of process 800 may be divided into additional blocks, combined into fewer blocks, or eliminated, depending on the desired implementation. The blocks of process 800 may be performed in the order shown in FIG. 8 or in any other order, depending on the desired implementation. Process 800 may be implemented in the SFP+ module of FIG. 3 and FIG. 4. Process 800 may begin at 810.

At 810, process 800 may involve storing a program code and data related to transmitter and receiver circuits. Process 800 may proceed from 810 to 820.

At 820, process 800 may involve controlling a flash memory and communication between an input/output (IO) controller and the flash memory.

In some implementations, process 800 may also involve downloading a firmware with contacts of a transceiver module.

### Additional Notes

Although some embodiments are disclosed above, they are not intended to limit the scope of the present disclosure. It will be apparent to those skilled in the art that various modifications and variations can be made to the disclosed embodiments of the present disclosure without departing from the scope or spirit of the present disclosure. In view of the foregoing, the scope of the present disclosure shall be defined by the following claims and their equivalents.

1. A single-chip integrated circuit implementable in a transceiver module for high-speed optoelectronic transmitting and receiving, comprising:
a laser driver configured to accept a high-speed digital electrical signal and drive a laser diode to create an equivalent optical signal;
a limiting amplifier configured to accept high-speed small signals from an optical detector and amplifiers and limit the high-speed small signals to create a uniform-amplitude digital electrical signal;
a flash memory configured to store a program code and data related to transmitter and receiver circuits; and
a micro-programmed controller unit (MCU) configured to generate control signals to control the laser driver and the limiting amplifier according to the data stored in the flash memory.

2. The single-chip integrated circuit of claim 1, further comprising:
an analog-to-digital converter (ADC) configured to receive a plurality of analog signals and convert the received analog signals to digital values.

3. The single-chip integrated circuit of claim 2, further comprising:
a temperature sensor configured to generate an analog temperature signal which is proportional to a temperature of the transceiver module, wherein the ADC converts the analog temperature signal into a digital temperature value to compensate a laser bias and a modulation current.

4. The single-chip integrated circuit of claim 2, further comprising:
a voltage sensor configured to generate an analog voltage signal, wherein the ADC converts the analog voltage signal into a digital voltage value.

5. The single-chip integrated circuit of claim 1, further comprising:
an input/output (IO) controller configured to handle low-speed electrical contacts of an optical transceiver module.

6. The single-chip integrated circuit of claim 1, further comprising:
a static random access memory (SRAM) configured to perform program running and store information related to transmitter and receiver circuits.

7. The single-chip integrated circuit of claim 1, further comprising:
a two-wire serial interface configured to communicate between a mother board and the transceiver module.

8. A single-chip integrated circuit for digital diagnostic monitoring in an optical transceiver module, comprising:
a laser driver configured to receive a high-speed digital electrical signal and drive a laser diode to create an equivalent optical signal;
a limiting amplifier configured to receive high-speed small signals from an optical detector and amplifiers to limit the received signals to create a uniform-amplitude digital electrical signal;
a flash memory configured to store program code and calibration constants for calibrating diagnostic monitoring data; and
a micro-programmed controller unit (MCU) configured to calculate and calibrate the diagnostic monitoring data which comprises temperature, supply voltage, TX bias current, TX output optical power, RX received optical power, or a combination thereof.

9. The single-chip integrated circuit of claim 8, further comprising:
an analog-to-digital converter (ADC) configured to receive a plurality of analog signals from a receiver optical sub-assembly (ROSA), a transmitter optical sub-assembly (TOSA), a laser driver bias current, a temperature sensor and a voltage sensor, and convert the received analog signals to digital values.

10. The single-chip integrated circuit of claim 9, further comprising:
a temperature sensor configured to generate an analog temperature signal which is proportional to a temperature of the transceiver module, wherein the ADC converts the analog temperature signal into a digital temperature value for temperature monitoring.

11. The single-chip integrated circuit of claim 9, further comprising:
a voltage sensor configured to generate an analog voltage signal, wherein the ADC converts the analog temperature signal into a digital voltage value for monitoring of a power supply voltage.

12. The single-chip integrated circuit of claim 8, further comprising:
a static random access memory (SRAM) for program running and storing digital diagnostic monitoring values.

13. The single-chip integrated circuit of claim 12, further comprising:
a two-wire serial interface configured to report the digital diagnostic monitoring values to a mother board.

14. A single-chip integrated circuit for handling low-speed electrical contacts in an optical transceiver module, comprising:
a laser driver configured to receive a high-speed digital electrical signal and drive a laser diode to create an equivalent optical signal;
a limiting amplifier configured to receive high-speed small signals from an optical detector and amplifiers to limit the received signals to create a uniform-amplitude digital electrical signal; and
a micro-programmed controller unit (MCU) configured to convey to a mother board interface a loss of signal (LOS) received from the limiting amplifier and a transmitter fault signal from the laser driver, and further configured to convey to a transmitter circuit a transmitter disable signal received from the mother board interface.

15. The single-chip integrated circuit of claim 14, further comprising:
an input/output (IO) controller configured to handle low-speed electrical contacts of an optical transceiver module.

16. The single-chip integrated circuit of claim 14, further comprising:
a static random access memory (SRAM) configured to perform program running and store temporary variable values.

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)
